(19) United States
(12) Patent Application Publication
(10) Pub. No.: US 2015/0008028 A1
(43) Pub. Date: Jan. 8, 2015

(54) ELECTRONIC APPARATUS AND MODULE

(71) Applicant: Kabushiki Kaisha Toshiba, Tokyo (JP)

(72) Inventor: Koji Tada, Hamura-shi (JP)

(21) Appl. No.: 13/935,909

(22) Filed: Jul. 5, 2013

(51) Int. Cl. H05K 1/11

(52) U.S. Cl. CPC H05K 1/11; H05K 1/115
USPC 174/266; 174/261

(57) ABSTRACT

According to one embodiment, an electronic apparatus includes, a substrate provided with a plurality of depressions, a stud which has a plurality of projections located in the depressions and which is fixed to the substrate, and a solder connection portion intervening between the substrate and the stud.

### FIELD

Embodiments described herein relate generally to an electronic apparatus having a printed circuit board.

### BACKGROUND

Printed wiring boards having a stud have been disclosed. The stud is used to, for example, connect the printed wiring boards. The stud connects the printed wiring boards to improve the degree of integration of components mounted on the printed wiring boards. Thus, the stud is concerned with the connection of the components. Therefore, there are needs for the improvement of the stud to improve product reliability.

An object of the present invention is to provide an electronic apparatus capable of reliability improvement.

### BRIEF DESCRIPTION OF THE DRAWINGS

FIG. 1 is an exemplary perspective view showing a portable computer which is an example of an electronic apparatus according to a first embodiment;

FIG. 2 is an exemplary partial enlarged front view of a printed circuit board to be housed in the portable computer shown in FIG. 1;

FIG. 3 is an exemplary partial enlarged top view of the printed circuit board to be housed in the portable computer shown in FIG. 2;

FIG. 4 is an exemplary sectional view of the printed circuit board taken along line F4-F4 shown in FIG. 3;

FIG. 5 is an exemplary front view of a stud of the printed circuit board shown in FIG. 2;

FIG. 6 is an exemplary bottom view of the stud of the printed circuit board shown in FIG. 5;

FIG. 7 is an exemplary sectional view of the stud taken along line F7-F7 shown in FIG. 6;

FIG. 8 is an exemplary top view of a stud of a printed circuit board of a portable computer according to a second embodiment;

FIG. 9 is an exemplary front view of the stud shown in FIG. 8;

FIG. 10 is an exemplary bottom view of the stud shown in FIG. 8;

FIG. 11 is an exemplary sectional view of the printed circuit board taken along line F10-F10 shown in FIG. 10;

FIG. 12 is an exemplary top view of a stud of a printed circuit board of a portable computer according to a third embodiment;

FIG. 13 is an exemplary front view of the stud shown in FIG. 12;

FIG. 14 is an exemplary bottom view of the stud shown in FIG. 12;

FIG. 15 is an exemplary sectional view of the printed circuit board taken along line F15-F15 shown in FIG. 14;

FIG. 16 is an exemplary top view of a stud of a printed circuit board of a portable computer according to a fourth embodiment;

FIG. 17 is an exemplary sectional view of the printed circuit board taken along line F17-F17 shown in FIG. 16;

FIG. 18 is an exemplary top view of a printed circuit board of a portable computer according to a fifth embodiment; and

FIG. 19 is an exemplary sectional view of the printed circuit board taken along line F19-F19 shown in FIG. 18.

### DETAILED DESCRIPTION

Various embodiments will be described hereinafter with reference to the accompanying drawings.

In general, according to one embodiment, an electronic apparatus comprises a substrate provided with a plurality of depressions, a stud which has a plurality of projections located in the depressions and which is fixed to the substrate, and a solder connection portion intervening between the substrate and the stud.

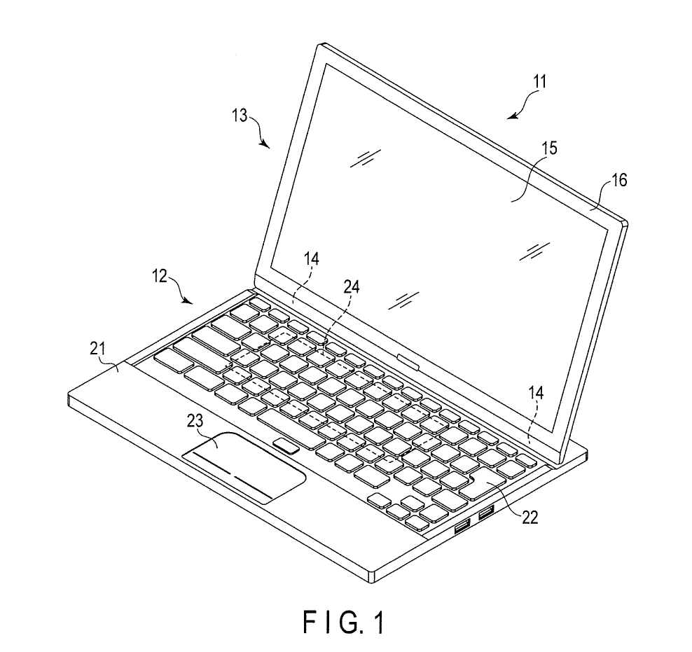

An embodiment of an electronic apparatus is described below with reference to FIG. 1 to FIG. 7. In an example described in the present embodiment, the electronic apparatus is applied to a portable computer by way of example.

As shown in FIG. 1, a portable computer 11 comprises a body 12, a display 13, and a hinge 14 provided between the body 12 and the display 13. The hinge 14 rotatably supports the display 13.

The display 13 has a display panel 15, and a display case 16 surrounding the display panel 15. The display case 16 is made of, for example, a synthetic resin material. Although the display panel 15 comprises a liquid crystal display panel in the present embodiment, the display panel 15 may be a display panel of some other type such as a plasma display panel, an organic electroluminescent display panel, a plastic display panel, or a sheet display panel.

The body 12 comprises a case 21 formed by, for example, a synthetic resin material into a box shape, a keyboard 22 provided on the upper surface (top wall) of the case 21, a touchpad 23 provided on the upper surface of the case 21, and a printed circuit board 24 (motherboard, main board) housed in the case 21.

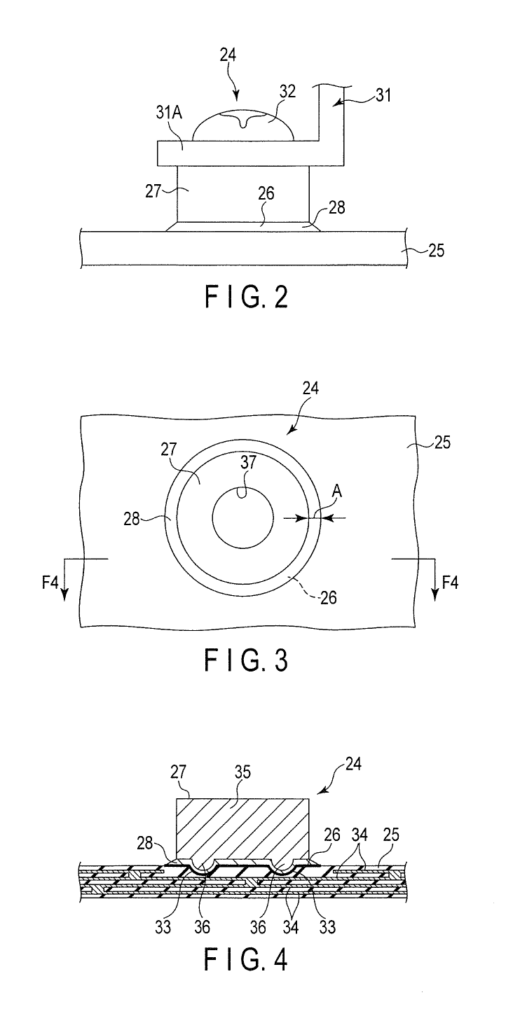

The printed circuit board 24 is an example of a module housed in the case 21. As shown in FIG. 2, the printed circuit board 24 has a substrate 25 comprising a printed wiring board, an unshown CPU mounted on the substrate 25, a pad 26 provided on the substrate 25, a stud 27 fixed to the substrate 25, a solder connection portion 28 intervening between the substrate 25 and the stud 27, a fixed portion 31A (leg) of a component 31 fixed to the stud 27, and a fixing member 32 for fixing the fixed portion 31A to the stud 27. The fixing member 32 comprises, for example, a screw.

In the present embodiment, the component 31 comprises, for example, a fan unit for cooling the CPU and components inside the case 21 or on the substrate 25. The fan unit is only illustrative. The component 31 may be a component of some other type such as a heat sink, a wireless LAN module, a hard disk drive (HDD), an optical disk drive (ODD), some other printed circuit board, an SSD equipped with a plurality of flash memories, a speaker, or a television tuner.

As shown in FIG. 3 and FIG. 4, the substrate 25 is a multilayer substrate (printed wiring board) having a stack of metal layers. The substrate 25 has a plurality of depressions 33 at positions overlapping the pad 26. The substrate 25 has a plurality of wiring layers 34 within the range of its thickness dimension. The wiring layers 34 are also disposed at positions corresponding to the depressions 33 (positions overlapping the depressions 33). In the present embodiment, for example, three depressions 33 are provided. Each of the depressions 33 is hemispherically depressed from the surface of the substrate 25 along the shape of each of projections 36 described later. The depressions 33 are laser via holes formed by laser. Each of the depressions 33 has a depth of, for example, 50 to 70 μm. The number of depressions 33 is not exclusively three, and may be two or may be four or more.

The pad 26 is provided on the substrate 25 to cover the depressions 33 from above. The pad 26 is circularly formed along the shape of the stud 27, and has a size (diameter, area) larger than the size (diameter, area) of the stud 27. A dimension A of the margin of the pad 26 for the stud 27 is, for example, 0.5 to 1.0 mm. The pad 26 is formed, for example, by plating the surface of the substrate 25 in which the depressions have been formed by laser in advance.

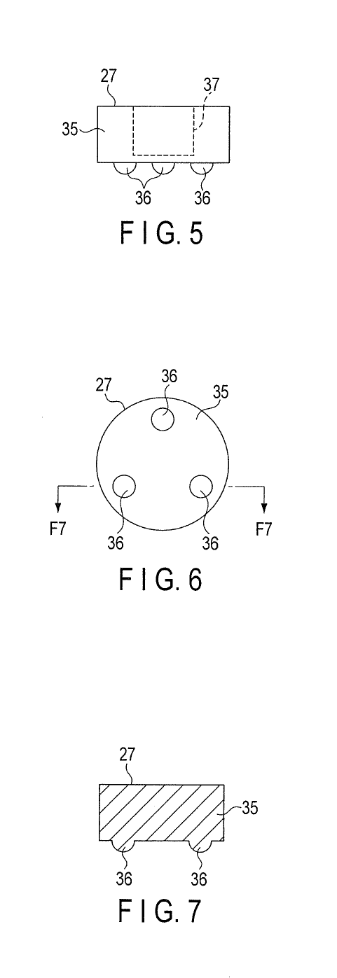

As shown in FIG. 5 to FIG. 7, the stud 27 is a surface mounting type stud formed by a metallic material. The stud 27 has a cylindrically formed stud body 35, and a plurality of projections 36 projecting from one surface of the stud body 35 toward the substrate 25. An internal thread hole 37 for fixing the fixing member is provided on the other surface of the stud body 35 opposite to the one surface. The projections 36 are used to position the stud 27 relative to the substrate 25. In the present embodiment, the number of projections 36 is three which is equal to the number of depressions 33. The number of projections 36 is not exclusively three, and may be two or may be four or more in accordance with the number of depressions 33.

The projection 36 is hemispherically formed along the shape of the depression 33. The projection 36 has a height substantially equal to the depth of the depression 33, and has a height of, for example, 50 to 70 μm. Each of the projections 36 is fitted in the depression 33 (located in the depression 33). The stud 27 is formed, for example, by cutting, but may be formed by forging or some other means.

As shown in FIG. 3 and FIG. 4, the solder connection portion 28 is fixed to the pad 26. The solder connection portion 28 is formed by solidifying, in a reflow oven, paste solder printed on the pad 26. The solder connection portion 28 intervenes between the substrate 25 and the stud 27. The solder connection portion 28 also intervenes between the depression 33 of the substrate 25 and the projection 36 of the stud 27.

According to the first embodiment, the portable computer 11 comprises the substrate 25 provided with the depressions 33, the stud 27 which has the projections 36 located in the depressions 33 and which is fixed to the substrate 25, and the solder connection portion 28 intervening between the substrate 25 and the stud 27.

According to this configuration, it is not necessary to provide the substrate 25 with a through-hole for fixing the stud 27 to the substrate 25, the degree of freedom in the designing of circuit traces can be improved, and the density of the traces can be increased. As the projections 36 are located in the depressions 33, it is possible to prevent the floating of the stud 27 on the substrate 25 (on the molten solder) and the displacement of the stud 27. This can improve the accuracy of the position of the stud 27.

The portable computer 11 comprises the pad 26 which is provided on the substrate 25 and to which the solder connection portion 28 is fixed. The depressions 33 are provided at positions overlapping the pad 26. This configuration prevents the decrease of the mounting areas of other components on the substrate 25 and enables highly dense mounting on the substrate 25 even when a plurality of depressions 33 are provided.

The solder connection portion 28 intervenes between the projections 36 and the depressions 33. This configuration can improve the reliability of the part that fixes the stud 27 to the substrate 25.

The portable computer 11 comprises the wiring layers 34 which are provided within a thickness dimension of the substrate 25 and which are also provided at positions corresponding to the stud 27. This configuration allows traces to be let through the part corresponding to the stud 27, and can improve the degree of freedom in the designing of circuit traces.

The projection 36 is hemispherical, and the depression 33 is hemispherically depressed along the projection 36. This configuration allows a larger area of contact between the stud 27 and the substrate 25, and can improve the reliability of the part that fixes the stud 27 to the substrate 25. This configuration also allows the projection 36 to more easily fit into the depression 33, and can improve workability in assembly.

The depression 33 is a laser via hole, and can therefore be easily and accurately formed.

### Second Embodiment

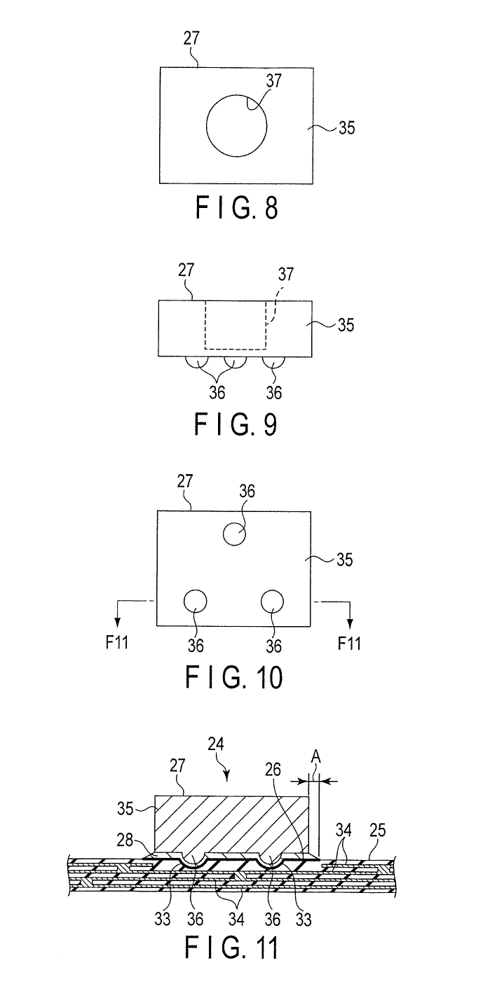

A second embodiment of an electronic apparatus is then described with reference to FIG. 8 to FIG. 11. In an example described in the present embodiment, the electronic apparatus is applied to a portable computer 11 by way of example. The portable computer 11 is different from that according to the first embodiment in the shape of a stud 27, but is the same as that according to the first embodiment in other respects. Therefore, the differences between the first embodiment and the second embodiment are mainly described, and the same parts are not described. The portable computer 11 according to the second embodiment is similar in appearance to the portable computer 11 shown in FIG. 1.

A printed circuit board 24 is an example of a module housed in a case 21. As shown in FIG. 11, the printed circuit board 24 has a substrate 25 comprising a printed wiring board, an unshown CPU mounted on the substrate 25, a pad 26 provided on the substrate 25, a stud 27 fixed to the substrate 25, a solder connection portion 28 intervening between the substrate 25 and the stud 27, a fixed portion 31A (leg) of a component 31 fixed to the stud 27, and a fixing member 32 for fixing the fixed portion 31A to the stud 27. The fixing member 32 comprises, for example, a screw.

As shown in FIG. 11, the substrate 25 is a multilayer substrate (printed wiring board) having a stack of metal layers. The substrate 25 has a plurality of depressions 33 at positions overlapping a plurality of metal layers. The substrate 25 has a plurality of wiring layers 34 within the range of its thickness dimension. The wiring layers 34 are also disposed at positions corresponding to the depressions 33 (positions overlapping the depressions 33). In the present embodiment, for example, three depressions 33 are provided. Each of the depressions 33 is hemispherically depressed from the surface of the substrate 25 along the shape of each of projections 36 described later. The depressions 33 are laser via holes formed by laser. Each of the depressions 33 has a depth of, for example, 50 to 70 μm.

The pad 26 is provided on the substrate 25 to cover the depressions 33 from above. The pad 26 is circularly formed along the shape of the stud 27, and has a size (diameter, area) larger than the size (diameter, area) of the stud 27. A dimension A of the margin of the pad 26 for the outer edge of the stud 27 is, for example, 0.5 to 1.0 mm. The pad 26 is formed, for example, by plating the surface of the substrate 25 in which the depressions 33 have been formed by laser in advance.

As shown in FIG. 8, FIG. 9, and FIG. 10, the stud 27 has a stud body 35 formed into the shape of a rectangular parallelepiped (quadratic prism), and a plurality of projections 36 projecting from one surface of the stud body 35 toward the substrate 25. An internal thread hole 37 for fixing the fixing member 32 is provided on the other surface of the stud body 35 opposite to the one surface. In the present embodiment, the number of projections 36 is three which is equal to the number of depressions 33. The projection 36 has a height substantially equal to the depth of the depression 33, and has a height of, for example, 50 to 70 μm. Each of the projections 36 is fitted in the depression 33 (located in the depression 33). The stud 27 is formed, for example, by cutting.

As shown in FIG. 11, the solder connection portion 28 is fixed to the pad 26. The solder connection portion 28 intervenes between the substrate 25 and the stud 27. The solder connection portion 28 also intervenes between the depression 33 of the substrate 25 and the projection 36 of the stud 27.

According to the second embodiment, even if the stud 27 is in the shape of a rectangular parallelepiped, it is not necessary to provide the substrate 25 with a through-hole for fixing the stud 27 to the substrate 25, and the degree of freedom in the designing of circuit traces can be improved. Moreover, when solder has melted during reflow, it is possible to prevent the floating of the stud 27 on the substrate 25 (on the molten solder) and the displacement of the stud 27.

### Third Embodiment

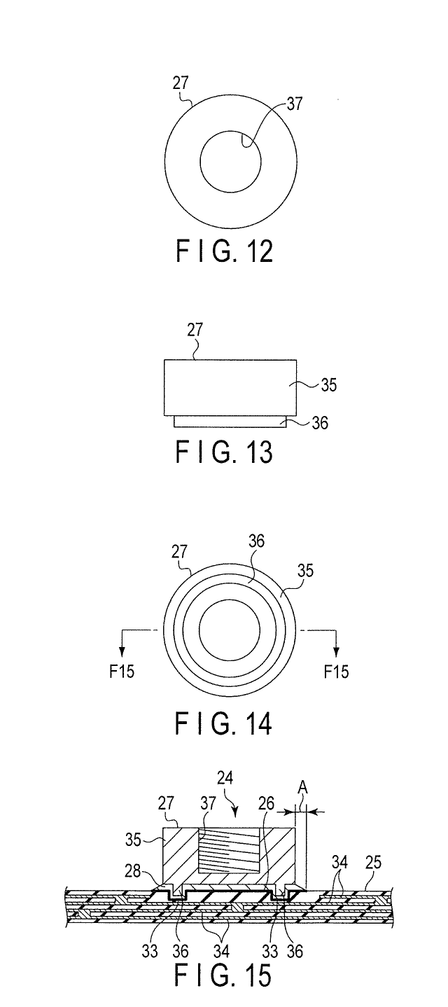

A third embodiment of an electronic apparatus is then described with reference to FIG. 12 to FIG. 15. In an example described in the present embodiment, the electronic apparatus is applied to a portable computer 11 by way of example. The portable computer 11 is different from that according to the first embodiment in the shape of a depression 33 of a substrate 25 and a projection 36 of a stud 27, but is the same as that according to the first embodiment in other respects. Therefore, the differences between the first embodiment and the third embodiment are mainly described, and the same parts are not described. The portable computer 11 according to the third embodiment is similar in appearance to the portable computer 11 shown in FIG. 1.

A printed circuit board 24 is an example of a module housed in a case 21. As shown in FIG. 15, the printed circuit board 24 has a substrate 25 comprising a printed wiring board, an unshown CPU mounted on the substrate 25, a pad 26 provided on the substrate 25, a stud 27 fixed to the substrate 25, a solder connection portion 28 intervening between the substrate 25 and the stud 27, a fixed portion 31A (leg) of a component 31 fixed to the stud 27, and a fixing member 32 for fixing the fixed portion 31A to the stud 27. The fixing member 32 comprises, for example, a screw.

The substrate 25 is a multilayer substrate (printed wiring board) having a stack of metal layers. The substrate 25 has one depression 33 which is substantially annularly depressed and which is located at a position overlapping the pad 26. The substrate 25 has a plurality of wiring layers 34 within the range of its thickness dimension. The wiring layers 34 are also disposed at a position corresponding to the depression 33 (position overlapping the depression 33). The depression 33 is a laser via hole formed by laser. The depression 33 is depressed from the surface of the substrate 25 along the shape of the projection 36 described later. The depression 33 has a depth of, for example, 50 to 70 μm. The depression 33 has only to be substantially annular, and may be, for example, in the shape of a partially discontinuous ring.

The pad 26 is provided on the substrate 25 to cover the depression 33 from above. The pad 26 is circularly formed along the shape of the stud 27, and has a size (diameter, area) larger than the size (diameter, area) of the stud 27. A dimension A of the margin of the pad 26 for the outer edge of the stud 27 is, for example, 0.5 to 1.0 mm. The pad 26 is formed, for example, by plating the surface of the substrate 25 in which the depression 33 has been formed by laser in advance.

As shown in FIG. 12 to FIG. 14, the stud 27 has a cylindrically formed stud body 35, and the projection 36 annularly projecting from one surface of the stud body 35 toward the substrate 25. An internal thread hole 37 for fixing the fixing member 32 is provided on the other surface of the stud body 35 opposite to the one surface.

The projection 36 is substantially annular. The projection 36 is fitted in the depression 33 (located in the depression 33). The projection 36 has a height substantially equal to the depth of the depression 33, has a height of, for example, 50 to 70 μm. The stud 27 is formed, for example, by cutting, but may be formed by forging or some other means. The projection 36 has only to be substantially annular, and may be partially discontinuously annular.

As shown in FIG. 15, the solder connection portion 28 is fixed to the pad 26. The solder connection portion 28 intervenes between the substrate 25 and the stud 27. The solder connection portion 28 also intervenes between the depression 33 of the substrate 25 and the projection 36 of the stud 27.

According to the present embodiment, the portable computer 11 comprises the substrate 25 provided with the substantially annularly depressed depression 33, the projection 36 which substantially annularly projects toward the substrate 25 and which is fitted into the depression 33, the stud 27 fixed to the substrate 25, and the solder connection portion 28 intervening between the substrate 25 and the stud 27.

According to this configuration, it is not necessary to provide the substrate 25 with a through-hole for fixing the stud 27 to the substrate 25, and the degree of freedom in the designing of circuit traces can be improved. Moreover, when solder is melted in a reflow oven, the projection 36 only rotates along the depression 33, and the stud 27 does not float on the substrate 25 (on the molten solder). It is thus possible to prevent the displacement of the stud 27 during reflow.

### Fourth Embodiment

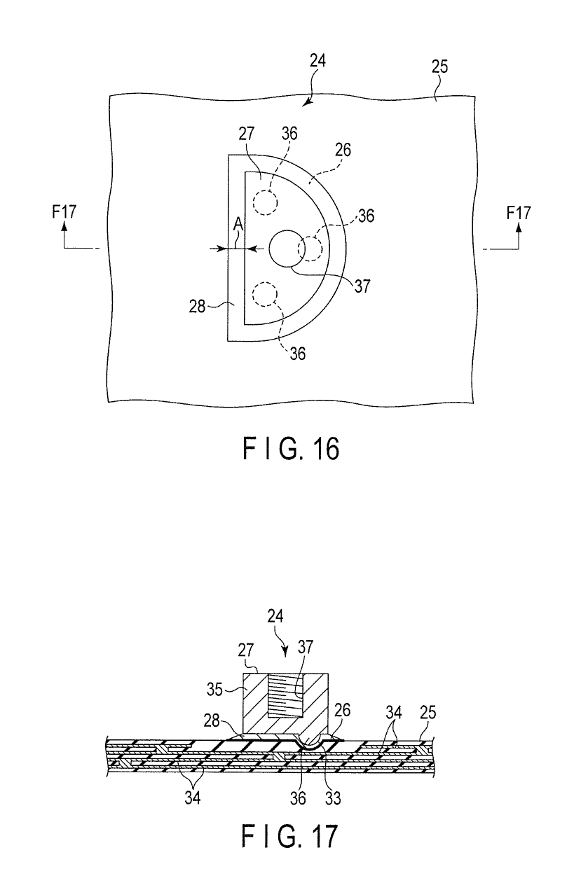

A fourth embodiment of an electronic apparatus is then described with reference to FIG. 16 and FIG. 17. In an example described in the present embodiment, the electronic apparatus is applied to a portable computer 11 by way of example. The portable computer 11 is different from that according to the first embodiment in the shape of a stud 27 and a pad 26, but is the same as that according to the first embodiment in other respects. Therefore, the differences between the first embodiment and the fourth embodiment are mainly described, and the same parts are not described. The portable computer 11 according to the fourth embodiment is similar in appearance to that shown in FIG. 1.

A printed circuit board 24 is an example of a module housed in a case 21. As shown in FIG. 17, the printed circuit board 24 has a substrate 25 comprising a printed wiring board, an unshown CPU mounted on the substrate 25, the pad 26 provided on the substrate 25, the stud 27 fixed to the substrate 25, a solder connection portion 28 intervening between the substrate 25 and the stud 27, a fixed portion 31A (leg) of a component 31 fixed to the stud 27, and a fixing member 32 for fixing the fixed portion 31A to the stud 27. The fixing member 32 comprises, for example, a screw.

As shown in FIG. 17, the substrate 25 is a multilayer substrate (printed wiring board) having a stack of metal layers. The substrate 25 has a plurality of depressions 33 at positions overlapping the pad 26. The substrate 25 has a plurality of wiring layers 34 within the range of its thickness dimension. The wiring layers 34 are also disposed at positions corresponding to the depressions 33 (positions overlapping the depressions 33). In the present embodiment, for example, three depressions 33 are provided. Each of the depressions 33 is hemispherically depressed from the surface of the substrate 25 along the shape of each of projections 36 described later. The depressions 33 are laser via holes formed by laser. Each of the depressions 33 has a depth of, for example, 50 to 70 μm. The number of depressions 33 is not exclusively three, and may be two or may be four or more.

The pad 26 is provided on the substrate 25 to cover the depressions 33 from above. The pad 26 is formed into a “D” shape along the shape of the stud 27, and has a size (diameter, area) larger than the size (diameter, area) of the stud 27. As shown in FIG. 16, a dimension A of the margin of the pad 26 for the outer edge of the stud 27 is, for example, 0.5 to 1.0 mm. The pad 26 is formed, for example, by plating the surface of the substrate 25 in which the depressions 33 have been formed by laser in advance.

As shown in FIG. 16, the stud 27 has a stud body 35 which is D-shaped (semicircular) when viewed from its end face, and a plurality of projections 36 projecting from one surface of the stud body 35 toward the substrate 25. An internal thread hole 37 for fixing the fixing member 32 is provided on the other surface of the stud body 35 opposite to the one surface. In the present embodiment, the number of projections 36 is three which is equal to the number of depressions 33. The number of projections 36 is not exclusively three, and may be two or may be four or more in accordance with the number of depressions 33.

The projection 36 is hemispherically formed along the shape of the depression 33. The projection 36 has a height substantially equal to the depth of the depression 33, and has a height of, for example, 50 to 70 μm. Each of the projections 36 is fitted in the depression 33 (located in the depression 33). The stud 27 is formed, for example, by cutting, but may be formed by forging or some other means.

As shown in FIG. 17, the solder connection portion 28 is fixed to the pad 26. The solder connection portion 28 is formed by solidifying, in a reflow oven, paste solder printed on the pad 26. The solder connection portion 28 intervenes between the substrate 25 and the stud 27. The solder connection portion 28 also intervenes between the depression 33 of the substrate 25 and the projection 36 of the stud 27.

According to the present embodiment, it is not necessary to provide the substrate 25 with a through-hole for fixing the stud 27 to the substrate 25, and the degree of freedom in the designing of circuit traces can be improved. When solder has melted during reflow, it is possible to prevent the floating of the stud 27 on the substrate 25 (on the molten solder) and the displacement of the stud 27. Moreover, as the pad 26 is shaped along the stud 27, the range in which the stud 27 is movable on the pad 26 is reduced. This, coupled with the configuration of the projections 36 described above, can further reduce the risk of the rotation of the stud 27 relative to the pad 26 during a reflow process.

### Fifth Embodiment

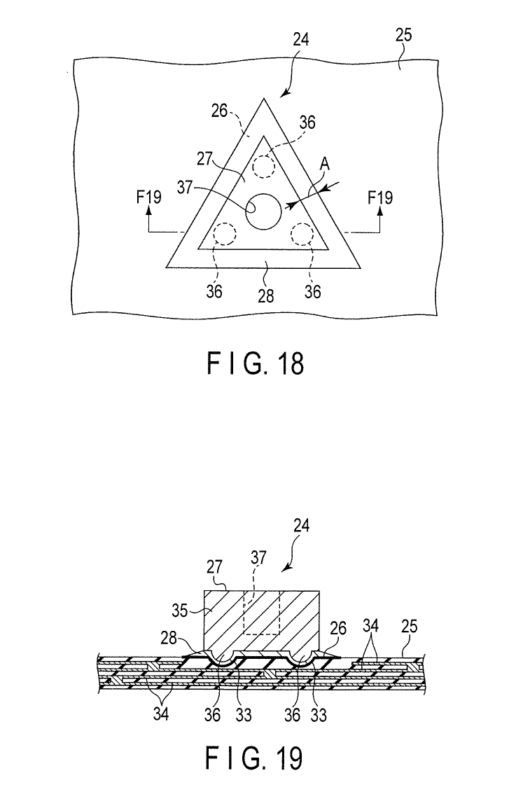

A fifth embodiment of an electronic apparatus is then described with reference to FIG. 18 and FIG. 19. In an example described in the present embodiment, the electronic apparatus is applied to a portable computer 11 by way of example. The portable computer 11 is different from that according to the first embodiment in the shape of a stud 27 and a pad 26, but is the same as that according to the first embodiment in other respects. Therefore, the differences between the first embodiment and the fifth embodiment are mainly described, and the same parts are not described. The portable computer 11 according to the fifth embodiment is similar in appearance to that shown in FIG. 1.

A printed circuit board 24 is an example of a module housed in a case 21. As shown in FIG. 19, the printed circuit board 24 has a substrate 25 comprising a printed wiring board, an unshown CPU mounted on the substrate 25, the pad 26 provided on the substrate 25, the stud 27 fixed to the substrate 25, a solder connection portion 28 intervening between the substrate 25 and the stud 27, a fixed portion 31A (leg) of a component 31 fixed to the stud 27, and a fixing member 32 for fixing the fixed portion 31A to the stud 27. The fixing member 32 comprises, for example, a screw.

The substrate 25 is a multilayer substrate (printed wiring board) having a stack of metal layers. The substrate 25 has a plurality of depressions 33 at positions overlapping the pad 26. The substrate 25 has a plurality of wiring layers 34 within the range of its thickness dimension. The wiring layers 34 are also disposed at positions corresponding to the depressions 33 (positions overlapping the depressions 33). In the present embodiment, for example, three depressions 33 are provided. Each of the depressions 33 is hemispherically depressed from the surface of the substrate 25 along the shape of each of projections 36 described later. The depressions 33 are laser via holes formed by laser. Each of the depressions 33 has a depth of, for example, 50 to 70 μm. The number of depressions 33 is not exclusively three, and may be two or may be four or more.

The pad 26 is provided on the substrate 25 to cover the depressions 33 from above. The pad 26 is formed into a triangular shape along the shape of the stud 27 described later, and has a size (diameter, area) larger than the size (diameter, area) of the stud 27. As shown in FIG. 18, a dimension A of the margin of the pad 26 for the outer edge of the stud 27 is, for example, 0.5 to 1.0 mm. The pad 26 is formed, for example, by plating the surface of the substrate 25 in which the depressions 33 have been formed by laser in advance.

As shown in FIG. 18, the stud 27 has a stud body 35 formed into the shape of a triangular prism, and a plurality of projections 36 projecting from one surface of the stud body 35 toward the substrate 25. An internal thread hole 37 for fixing the fixing member 32 is provided on the other surface of the stud body 35 opposite to the one surface. In the present embodiment, the number of projections 36 is three which is equal to the number of depressions 33. The number of projections 36 is not exclusively three, and may be two or may be four or more in accordance with the number of depressions 33.

The projection 36 is hemispherically formed along the shape of the depression 33. The projection 36 has a height substantially equal to the depth of the depression 33, and has a height of, for example, 50 to 70 μm. Each of the projections 36 is fitted in the depression 33.

As shown in FIG. 19, the solder connection portion 28 is fixed to the pad 26. The solder connection portion 28 intervenes between the substrate 25 and the stud 27. The solder connection portion 28 also intervenes between the depression 33 of the substrate 25 and the projection 36 of the stud 27.

According to the present embodiment, it is not necessary to provide the substrate 25 with a through-hole for fixing the stud 27 to the substrate 25, and the degree of freedom in the designing of circuit traces can be improved. When solder has melted during reflow, it is possible to prevent the floating of the stud 27 on the substrate 25 (on the molten solder) and the displacement of the stud 27. Moreover, as the pad 26 is shaped along the stud 27, the range in which the stud 27 is movable on the pad 26 is reduced. This, coupled with the configuration of the projections 36 described above, can further reduce the risk of the rotation of the stud 27 relative to the pad 26 during a reflow process.

It should be appreciated that the electronic apparatus is not limited to the portable computer 11 according to the embodiments described above, and is also applicable to other electronic apparatuses such as a television, a mobile telephone, a tablet apparatus, a smartphone, and an electronic book reader which electronically displays books and images.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a substrate provided with a plurality of depressions;
a stud which has a plurality of projections located in the depressions and which is fixed to the substrate; and
a solder connection portion intervening between the substrate and the stud.

2. The electronic apparatus of claim 1, further comprising a pad which is provided on the substrate and to which the solder connection portion is fixed,
wherein the depressions are provided at positions overlapping the pad.

3. The electronic apparatus of claim 1, wherein the solder connection portion intervenes between the projections and the depressions.

4. The electronic apparatus of claim 1, further comprising a plurality of wiring layers which are provided within a thickness dimension of the substrate and which are also provided at positions corresponding to the depressions.

5. The electronic apparatus of claim 1, wherein the projections are hemispherical, and
the depressions are hemispherically depressed along the projections.

6. The electronic apparatus of claim 1, wherein the depressions are laser via holes.

7. An electronic apparatus comprising:
a substrate provided with a substantially annularly depressed depression;
a stud which has a projection and which is fixed to the substrate, the projection substantially annularly projecting toward the substrate and being fitted into the depression; and
a solder connection portion intervening between the substrate and the stud.

8. The electronic apparatus of claim 7, further comprising a pad which is provided on the substrate and to which the solder connection portion is fixed,
wherein the depression is provided at a position overlapping the pad.

9. The electronic apparatus of claim 7, wherein the solder connection portion intervenes between the projection and the depression.

10. A module comprising:
a substrate provided with a plurality of depressions;
a stud which has a plurality of projections located in the depressions and which is fixed to the substrate; and
a solder connection portion intervening between the substrate and the stud.

11. The module of claim 10, further comprising a pad which is provided on the substrate and to which the solder connection portion is fixed,
wherein the depressions are provided at positions overlapping the pad.

12. The module of claim 10, wherein the solder connection portion intervenes between the projections and the depressions.

13. The module of claim 10, further comprising a plurality of circuit layers which are provided within a thickness dimension of the substrate and which are also provided at positions corresponding to the depressions.

14. The module of claim 10, wherein the projections are hemispherical, and
the depressions are hemispherically depressed along the projections.

15. The module of claim 10, wherein the depressions are laser via holes.
